(19) United States
(12) Patent Application Publication
(10) Pub. No.: US 2004/0157443 A1
(43) Pub. Date: Aug. 12, 2004

(54) Semiconductor device and method for manufacturing the same

(75) Inventors: Yoshiaki Shimooka, Kawasaki-shi (JP); Noriaki Matsunaga, Chigasaki-shi (JP)

Correspondence Address: PILLSBURY WINTHROP, LLP, P.O. BOX 10500, MCLEAN, VA, 22102, US

(73) Assignee: KABUSHIKI KAISHA TOSHIBA, Tokyo (JP)

(21) Appl. No.: 10/769,894

(22) Filed: Feb. 3, 2004

Related U.S. Application Data
(62) Division of application No. 10/025,683, filed on Dec. 26, 2001, now abandoned.

(30) Foreign Application Priority Data
Dec. 27, 2000 (JP) 2000-399294

(51) Int. Cl. H01L 21/44

(52) U.S. Cl. 438/687

(57) ABSTRACT

A semiconductor device comprising an insulation layer formed on a surface of a semiconductor substrate, a wiring groove pattern which is formed in the insulation layer, a conductive diffusion-prevention layer which is formed on the inner surface of the wiring groove, and a Cu-based wiring layer formed in the wiring groove provided on the inner surface thereof with the conductive diffusion-prevention layer, wherein the Cu-based wiring contains sulfur at a ratio ranging from 10⁻³ atomic % to 1 atomic %.

### CROSS-REFERENCE TO RELATED APPLICATIONS

This application is based upon and claims the benefit of priority from the prior Japanese Patent Application No. 2000-399294, filed Dec. 27, 2000, the entire contents of which are incorporated herein by reference.

### BACKGROUND OF THE INVENTION

1. Field of the Invention

The present invention relates to a semiconductor device and the method of manufacturing the semiconductor device, and in particular, to a semiconductor device provided with Cu-based wiring and to the method of manufacturing such a semiconductor device.

2. Description of the Related Art

In recent years, the selection of multi-layer wiring materials for large scale integrated circuits (LSIs) is being increasingly shifted from aluminum (Al) alloys to copper (Cu). Since the bulk material of Cu is lower not only in its self-diffusion coefficient, but also in its specific resistance as compared with Al, for example, the specific resistance of Cu being about 35% lower than that of Al, it is possible to improve the Electro-Migration (EM) resistivity and to reduce the total wiring resistance.

However, use of Cu is accompanied by the following defects.

(1) Since Cu exhibits a large diffusion coefficient in Si as well as in SiO₂, Cu is allowed to reach the channel region of a transistor thereby establishing an energy level at the center of the band gap, thus making the electrical properties of the transistor deteriorate.

(2) Since copper chlorides have a low vapor pressure, it is difficult to perform etching using an etching gas containing chlorine atoms with a resist being employed as a mask.

(3) Since Cu can be easily eroded, the disconnection of a fine wiring pattern as well as the peeling of insulating film formed on the surface of the pattern may easily occur.

Some of the aforementioned defects can be overcome by the following measures. Namely, with respect to the aforementioned defect (1), it is possible to suppress the diffusion of Cu by surrounding Cu with a layer of material which enables the diffusion coefficient of Cu to be minimized, such as a barrier metal such as Ta, TaN, or TiN, or by making use of an insulating film composed of SiN, etc. With respect to the aforementioned defect (2), it is possible to form a wiring, without undergoing etching processes, by making use of a damascene method wherein Cu is deposited on the surface of an insulating film provided, in advance, with a pattern of grooves thereby to fill the grooves with Cu, after which redundant portions of Cu which are deposited on the surface of the insulating film are selectively removed by means of polishing. Further, with respect to the aforementioned defect (3) which is related to easy oxidization, the defect can be overcome by removing the oxide layer of Cu by subjecting the surface of Cu to a reduction treatment using hydrogen gas or to a treatment using a chemical solution.

However, in spite of these countermeasures, there still remains the problem that the phenomenon of the peeling of insulating film formed around the wiring cannot be prevented, and hence it is desired now to make clear the cause of this phenomenon and to take suitable countermeasures.

### BRIEF SUMMARY OF THE INVENTION

According to one aspect of the present invention, there is provided a semiconductor device comprising a Cu-based wiring layer containing a Cu-based metal as a main component and formed on a surface of semiconductor substrate; and an insulating layer formed to surround the Cu-based wiring layer; wherein the Cu-based metal contains sulfur at a ratio ranging from 10⁻³ atomic % to 1 atomic %.

According to the other aspect of the present invention, there is also provided a semiconductor device comprising a Cu-based wiring layer containing a Cu-based metal as a main component and formed on a surface of a semiconductor substrate; and an insulating layer formed to surround the Cu-based wiring layer; wherein the Cu-based metal contains fluorine at a ratio ranging from 10⁻³ atomic % to 1 atomic %.

According to the other aspect of the present invention, there is also provided a method of manufacturing a semiconductor device, which comprises:

forming an insulating layer on a surface of a semiconductor substrate;

forming a wiring groove pattern in the insulating layer;

subjecting a resultant structure to a heat treatment in an inert atmosphere, in an atmosphere containing hydrogen or in a vacuum, to a plasma treatment in an atmosphere containing ammonia, or to a treatment using an ammonia solution;

forming a conductive diffusion-prevention layer on an inner surface of the wiring groove that has been subjected to any of aforementioned treatments and on a surface of the insulating layer that has been subjected to any of the aforementioned treatments;

forming a Cu-based metal layer on a surface of the conductive diffusion-prevention layer thereby to bury the wiring groove with Cu-based metal;

selectively removing portions of the Cu-based metal layer and of the conductive diffusion-prevention layer, which are deposited on regions other than the inner surface of the wiring groove thereby to form a Cu-based wiring layer inside the wiring groove; and

forming an insulating film which is capable of suppressing the diffusion of Cu-based metal on a surface of the Cu-based wiring layer and on a surface of the insulating layer;

wherein the Cu-based metal contains sulfur or fluorine at a ratio ranging from 10⁻³ atomic % to 1 atomic %.

According to the other aspect of the present invention, there is also provided a method of manufacturing a semiconductor device, which comprises:

forming an insulating layer on a surface of a semiconductor substrate;

forming a wiring groove pattern in the insulating layer;

forming a conductive diffusion-prevention layer on an inner surface of the wiring groove and on a surface of the insulating layer;

forming a Cu-based metal layer on a surface of the conductive diffusion-prevention layer thereby to bury the wiring groove with a Cu-based metal;

subjecting a resultant structure to a heat treatment in an inert atmosphere, in an atmosphere containing hydrogen or in a vacuum;

selectively removing portions of Cu-based metal layer and of the conductive diffusion-prevention layer, which are deposited on regions other than the inner surface of the wiring groove thereby to form a Cu-based wiring layer inside the wiring groove; and

forming an insulating film which is capable of suppressing the diffusion of Cu-based metal on a surface of the Cu-based wiring layer and on a surface of the insulating layer;

wherein the Cu-based metal contains sulfur at a ratio ranging from 10⁻³ atomic % to 1 atomic %.

According to the present invention, there is also provided a method of manufacturing a semiconductor device, which comprises:

forming an insulating layer on a surface of semiconductor substrate;

forming a wiring groove pattern in the insulating layer;

forming a conductive diffusion-prevention layer on an inner surface of the wiring groove and on a surface of the insulating layer;

forming a Cu-based metal layer on a surface of the conductive diffusion-prevention layer thereby to bury the wiring groove with a Cu-based metal;

selectively removing portions of the Cu-based metal layer and of the conductive diffusion-prevention layer, which are deposited on regions other than the inner surface of the wiring groove thereby to form a Cu-based wiring layer inside the wiring groove;

subjecting a resultant structure having the Cu-based wiring layer formed therein to a heat treatment in an inert atmosphere, in an atmosphere containing hydrogen or in a vacuum, to a plasma treatment in an atmosphere containing ammonia, or to a treatment using an ammonia solution; and

forming an insulating diffusion-prevention layer which is capable of suppressing the diffusion of Cu-based metal on a surface of the Cu-based wiring layer and on a surface of the insulating layer;

wherein the Cu-based metal contains sulfur or fluorine at a ratio ranging from 10⁻³ atomic % to 1 atomic %.

According to the other aspect of the present invention, there is further provided a method of manufacturing a semiconductor device, which comprises:

forming an insulating layer on a surface of a semiconductor substrate;

forming a wiring groove pattern in the insulating layer;

subjecting a resultant structure to a heat treatment in an inert atmosphere, in an atmosphere containing hydrogen or in a vacuum, to a plasma treatment in an atmosphere containing ammonia, or to a treatment using an ammonia solution;

forming a conductive diffusion-prevention layer on an inner surface of the wiring groove and on a surface of the insulating layer;

forming a Cu-based metal layer on a surface of the conductive diffusion-prevention layer thereby to bury the wiring groove with a Cu-based metal;

subjecting the Cu-based metal layer to a heat treatment in an inert atmosphere, in an atmosphere containing hydrogen or in a vacuum;

selectively removing portions of the Cu-based metal layer and of the conductive diffusion-prevention layer, which are deposited on regions other than the inner surface of the wiring groove thereby to form a Cu-based wiring layer inside the wiring groove;

subjecting a resultant structure having the Cu-based wiring layer formed therein to a heat treatment in an inert atmosphere, in an atmosphere containing hydrogen or in a vacuum, to a plasma treatment in an atmosphere containing ammonia, or to a treatment using an ammonia solution; and

forming an insulating diffusion-prevention layer which is capable of suppressing the diffusion of Cu-based metal on a surface of the Cu-based wiring layer and on a surface of the insulating layer;

wherein the Cu-based metal contains sulfur or fluorine at a ratio ranging from 10⁻³ atomic % to 1 atomic %.

### BRIEF DESCRIPTION OF THE SEVERAL VIEWS OF THE DRAWING

FIGS. 1A through 1F are cross-sectional views, each illustrating the method of forming damascene wiring portions of a semiconductor device provided with Cu multi-layer wiring according to one example of the present invention;

FIG. 2 is a flow chart illustrating, stepwise, the manufacturing process of a semiconductor device having a damascene wiring structure as Cu wiring;

FIG. 3 is a flow chart illustrating, stepwise, the manufacturing process of a semiconductor device having a damascene wiring structure as Cu wiring;

FIG. 4 is a flow chart illustrating, stepwise, the manufacturing process of a semiconductor device having a damascene wiring structure as Cu wiring;

FIG. 5 is a flow chart illustrating, stepwise, the manufacturing process of a semiconductor device having a damascene wiring structure as Cu wiring;

FIG. 6 is a photograph illustrating a state of the Cu multi-layer wiring structure that has been formed by the method of the present invention wherein the formation of copper sulfide compound is not recognized and the film peeling is also not recognized;

FIGS. 7A and 7B are photographs illustrating a state of the Cu multi-layer wiring structure that has been formed by the conventional method wherein the formation of copper sulfide compound is recognized and film peeling is also recognized; and

FIG. 8 is a photograph illustrating a state wherein a Cu multi-layer wiring structure has peeled due to a mismatching of the coefficient of thermal expansion between Cu and a low permittivity insulating film in a case where the Cu multi-layer wiring structure has been formed by a method which enables the sulfur component incorporated in a manufacturing process to be removed as much as possible.

### DETAILED DESCRIPTION OF THE INVENTION

Next, various embodiments of the present invention will be explained with reference to drawings.

According to the semiconductor device provided with a Cu-based wiring of the present invention, the content of sulfur or fluorine in the Cu-based wiring layer should be within the range of 10⁻³ atomic % to 1 atomic %, and preferably within the range of 10⁻² atomic % to 1 atomic %.

The Cu-based wiring of the present invention is formed of a Cu-based metal. As for the Cu-based metal, it is possible to employ Cu or a Cu alloy selected from the group consisting of Cu—Ag, Cu—Pt, Cu—Al, Cu—C and CuCo.

As one embodiment of the present invention, a conductive diffusion-prevention layer may be formed so as to surround the aforementioned Cu-based wiring in order to prevent the diffusion of Cu-based metal. This conductive diffusion-prevention layer may be composed of a material selected from the group consisting of Ta, TaN, TiN, Ti, TiN, WN, TiSiN, etc.

In place of or in addition to the conductive diffusion-prevention layer, an insulating diffusion-prevention layer (an insulating film which is capable of suppressing the diffusion of Cu-based metal) may be formed on the upper surface of the Cu-based wiring. As for this insulating diffusion-prevention layer, it is possible to employ SiN, SiC, SiCO, SiCN, etc.

The content of sulfur or fluorine in the Cu-based wiring can be analyzed by means of secondary ion mass spectrometry (SIMS), Fourier transform infrared spectrometry (FTIR), total reflection fluorescent X-ray spectrometry (TXRF), etc. Since the factors for the abnormal growth of Cu or the fluctuation of the coefficient of thermal expansion of Cu are not the sulfur or fluorine element that is bonded to another kind of atom, but the free sulfur or fluorine element, it is possible to analyze not only the total content of the sulfur or fluorine element by means of SIMS, but also the sulfur or fluorine element that has a bonding role by means of FTIR. Therefore, if these analysis methods are combined, the content of free sulfur or free fluorine which is the object of the present invention can be analyzed.

It has been found as a result of many studies made by the present inventors with respect to the phenomenon of the peeling of insulating layer or insulating film formed around wiring as well as the cause thereof that the peeling of the insulating layer or insulating film can be attributed to the existence of sulfur or fluorine in the insulating layer or in the wiring. The followings are detailed explanations of the results of analysis.

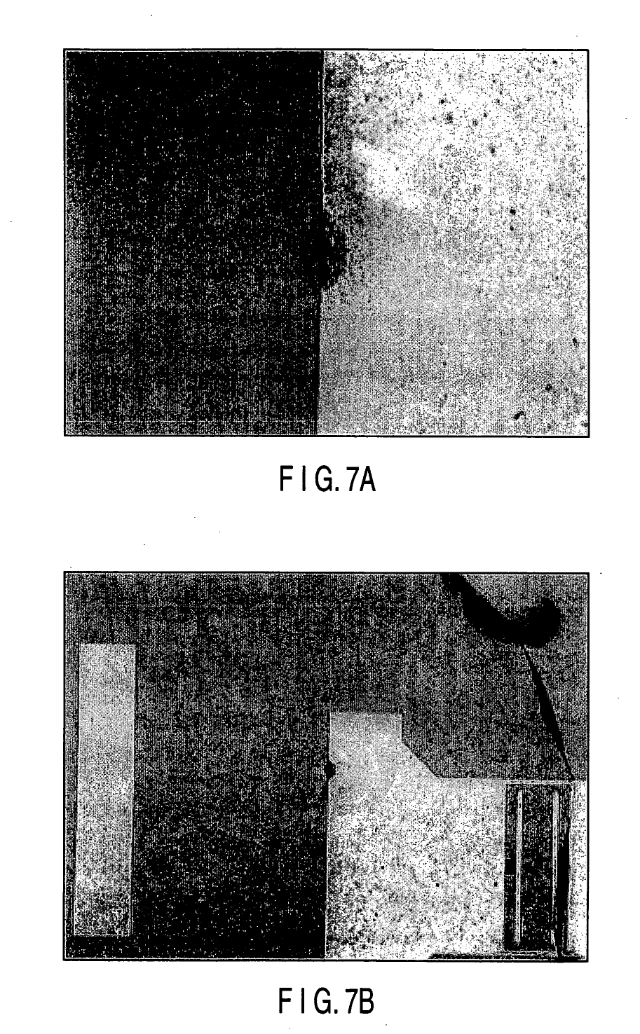

FIGS. 7A and 7B show a photomicrograph illustrating the state near the interface between an insulating layer and Cu wiring where the Cu wiring is formed inside the groove formed in the insulating layer by means of the damascene method. As shown in FIG. 7A, an abnormal growth was observed at an edge of the Cu wiring pattern. This abnormal growth was produced during the heat treatment process in the course of forming the Cu wiring pattern.

When a qualitative analysis was performed on this abnormal growth portion by means of energy dispersive X-ray analysis (EDX) or Auger electron spectroscopy (AES), the existence of sulfur (S) and Cu was detected, and at the same time, it was made clear that a copper sulfide compound was formed at an edge portion of the wiring pattern.

On the other hand, in the circumference of this abnormal growth portion, a portion thereof which indicates peeling of the insulating film was recognized as shown in FIG. 7B. This peeled portion was at the interface between the Cu wiring pattern and the insulating diffusion-prevention layer (for example, SiN film) and at the interface between the interlayer insulating film and the insulating diffusion-prevention layer (for example, SiN film).

Since sulfur is frequently included in a chemical solution to be employed for removing reaction products after the working of the insulating film (it includes a sulfur component at a ratio of 20 to 30% by weight), in a copper sulfate solution to be employed in a Cu plating process, or in a polishing solution (for example, ammonium peroxodisulfate) to be employed in chemical mechanical polishing (CMP), this sulfur component will originate from these solutions.

If the manufacturing process of a semiconductor device is carried out without taking any measures to deal with this problem, the sulfur component would be allowed to diffuse into the insulating film or to adhere to the surface of the wiring layer. As a result, the sulfur component is allowed to react with the copper thereby to produce a copper sulfide compound as the process proceeds, thus giving rise to peeling of an insulating film laminated on the wiring layer.

In particular, if a low permittivity insulating film exhibiting a relative permittivity of not more than 3.0, such as a coating type organic insulating film or a porous insulating film, is employed as an insulating layer in which a pattern of the wiring groove is to be formed, a chemical solution containing a sulfur component is prone to be absorbed by a modified region that has been exposed to an etching gas, or by a polished surface, so that as the steps of lamination proceeds, sulfur is allowed to diffuse into the wiring region thereby to produce copper sulfide compounds, thereby increasing the possibility of generating a defective pattern or the peeling of the interlayer insulating film that has been formed over the wiring pattern.

It is estimated through the qualitative analysis of such an abnormal growth portion at an edge portion of the Cu wiring pattern that the concentration of the sulfur component contained in the Cu wiring pattern might have been higher than 1 atomic %. Therefore, if the sulfur component is allowed to remain, even if locally, at a concentration of 1 atomic % or more in the conventional process of forming Cu-based wiring, it would greatly prevent the formation of a Cu-based wiring structure, in particular, a Cu-based multi-layer wiring structure.

In the case of a low permittivity insulating film such as a coating type organic insulating film or a porous insulating film, there is a possibility that fluorine (F) which is a constituent element of a CF-based gas employed in an etching process is allowed to enter into these insulating films during the etching work. It has been found that if such is the case, the diffusion of fluorine as well as the reaction of fluorine are caused to occur according to the same mechanism as that of sulfur, thereby forming a copper fluoride compound and hence giving rise to the peeling of an interlayer insulating film formed over wiring.

Whereas, according to one embodiment of the present invention, a step of removing sulfur components is included in the middle of the process for forming wiring, thereby making it possible to prevent the film peeling. This step of removing sulfur can be introduced into any occasion, i.e., after the step of forming a wiring groove patterns in an insulating layer, after the step of filling a Cu-based metal in the wiring grooves, or after the step of selectively removing portions of the Cu-based metal layer and of the conductive diffusion-prevention layer, which are deposited on regions other than the inner surface of the wiring grooves.

Further, the step of removing sulfur can be performed by heat treatment in an inert atmosphere, in an atmosphere containing hydrogen or in a vacuum, by a plasma treatment in an atmosphere containing ammonia, or by a treatment using an ammonia solution.

The heat treatment temperature should preferably be in the range of 200 to 500° C. As for the inert atmosphere, it is possible to use such gases as argon and nitrogen. As for the atmosphere containing hydrogen, it is preferable to employ an H2/N2 mixed atmosphere containing hydrogen at a ratio of 1 to 20% by volume.

By way of the aforementioned sulfur-removal step, the concentration of sulfur in the Cu-based wiring layer can be confined within the range of 10⁻³ atomic % to 1 atomic %, and preferably within the range of 10⁻² atomic % to 1 atomic %, and at the same time, the concentration of sulfur in the insulating layer can be confined to 1 atomic % or less.

As a result, it is possible to prevent the abnormality in the Cu wiring pattern as well as peeling of the interlayer insulating film due to the Cu wiring pattern abnormality.

In the case of fluorine also, by way of a similar fluorine-removal step, the concentration of fluorine in the Cu-based wiring layer can be confined within the range of 10⁻³ atomic % to 1 atomic %, and preferably within the range of 10⁻² atomic % to 1 atomic %, and at the same time, the concentration of fluorine in the insulating layer can be confined to 1 atomic % or less.

However, since a Cu layer is deposited on the entire surface subsequent to the step of burying the wiring groove pattern with a Cu-based metal, it is impossible to remove fluorine, so that this fluorine-removal step cannot be performed.

On the other hand, with respect to other causes of the peeling of the insulating film from the surface of Cu wiring, it can be conceivably ascribed to the difference in the coefficient of thermal expansion between Cu and the insulating layer or the insulating film formed around the Cu. Generally, the coefficient of thermal expansion of insulating film is expected to be within the range of about 1×10⁻⁶ to 1×10⁻⁵ [K⁻¹], whereas the coefficient of thermal expansion of a metallic material such as Cu is as large as about 1.5×10⁻⁵ to 4×10⁻⁵ [K⁻¹]. As this difference of the coefficient of thermal expansion becomes larger, the possibility of generating the film peeling becomes greater due to the mismatching of changes in volume of these materials in the heating step of the wiring-formation process. Therefore, even if it is possible to avoid the formation of a copper sulfide compound, the lamination for the Cu multi-layer wiring structure would be obstructed due to the aforementioned factor.

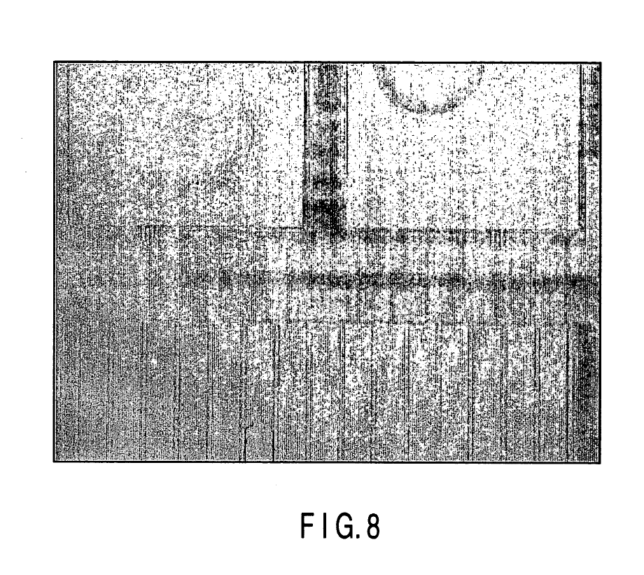

FIG. 8 is a photograph of a cross-sectional view of Cu wiring, which is a sample that has been manufactured by eliminating as far as possible any steps which are assumed to invite the intermingling of sulfur components during the process of forming Cu wiring. It was assumed that the concentration of sulfur in this sample of Cu wiring was less than 10⁻³ atomic %.

Specifically, in this process of forming the Cu wiring, the treatment of the insulating layer by making use of a chemical solution for removing reaction products after the formation of wiring groove pattern was eliminated, a sputter-reflow method was employed without employing a plating method in the Cu-filling step, and a polishing solution which is free from sulfur components was employed in the subsequent CMP process.

As a result, peeling of the insulating film from the wiring groove pattern was recognized. This peeled portion was found at the interface between the pattern of Cu wiring and the insulating diffusion-prevention layer (for example, an SiN film), thus indicating that as mentioned above, the peeling was assumed to be caused the mismatching in volume changes between Cu and the interlayer insulating film. As long as materials of different kinds are to be laminated, it may be impossible to make their coefficients of thermal expansion coincide. It is assumed however that, if the coefficients of thermal expansion can be made close to each other, film peeling can be suppressed.

Whereas, according to the present invention, the concentration of sulfur components in the Cu wiring was adjusted to 10⁻³ atomic % or more. As a result, sulfur was allowed to precipitate as an impurity at the grain boundary of Cu, thus reducing the coefficient of thermal expansion to the range of 0.5×10⁻⁵ to 1.5×10⁻⁵ [K⁻¹], thereby making it difficult to cause film peeling such as shown in FIG. 8 that might have occurred because of the difference in coefficients of thermal expansion between Cu and the interlayer insulating film. In the case of fluorine also, the concentration of fluorine in the Cu wiring should be adjusted to 10⁻³ atomic % or more.

The adjustment of the concentration of sulfur or fluorine in the Cu wiring to 10⁻³ atomic % or more can be achieved by treating the inner surfaces of the wiring groove pattern with a treatment solution containing sulfur or fluorine, other than the method wherein the sulfur or fluorine component that has been intermingled in the Cu wiring during the process of forming the Cu wiring is removed so as to control the concentration of sulfur or fluorine. Alternatively, the adjustment of concentration of sulfur or fluorine can be performed by making use of a sulfur or fluorine-containing polishing solution in the step of polishing and removing the part of the Cu-based metal layer and of the conductive diffusion-prevention layer that is deposited on regions other than the wiring groove pattern.

Alternatively, the intermingling of sulfur can be well controlled by a method wherein a seed layer is formed by making use of a sputter target containing the sulfur element, or a seed layer is formed by means of CVD method using a raw material gas containing the sulfur element, after which Cu is deposited by means of plating method. In the case of fluorine however, fluorine can be intermingled into Cu by forming a seed layer by means of the CVD method using a raw material gas containing the fluorine element.

As described above, when the concentration of sulfur or fluorine, both being an impurity, is controlled so as to meet not only the conditions for preventing film peeling due to the generation of a copper sulfide compound but also the conditions for preventing film peeling due to the difference in coefficient of thermal expansion, Cu-based wiring which is free from film peeling can be formed. Specifically, when the concentration of sulfur or fluorine is controlled within the range of 10⁻³ atomic % to 1 atomic %, and preferably within the range of 10⁻² atomic % to 1 atomic %, Cu-based wiring can be formed without the problem of film peeling.

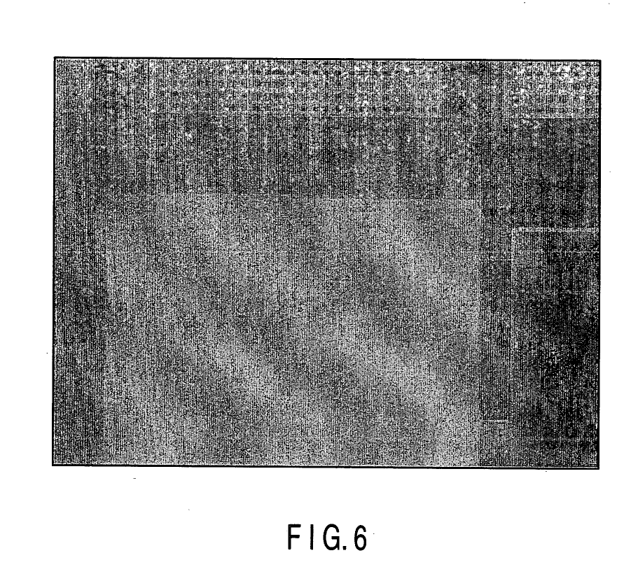

FIG. 6 is a photograph illustrating multi-layer wiring wherein the concentration of sulfur or fluorine in the Cu wiring was confined to the range of 10⁻³ atomic % to 1 atomic % by incorporating a step of removing sulfur or fluorine in the middle of the process of manufacturing a semiconductor device provided with a combination of a coated film of low permittivity and Cu-based wiring, i.e., by incorporating a step of treatment using NH₃ solution subsequent to the CMP process.

It will be seen from FIG. 6 that the multi-layer wiring was free from abnormality of the Cu wiring pattern and from film peeling, both of-which are illustrated in FIGS. 7A, 7B and 8. It will be clear from the above explanations that the present invention is useful for the formation of Cu-based wiring.

Next, various examples of the present invention will be explained as follows.

### EXAMPLE 1

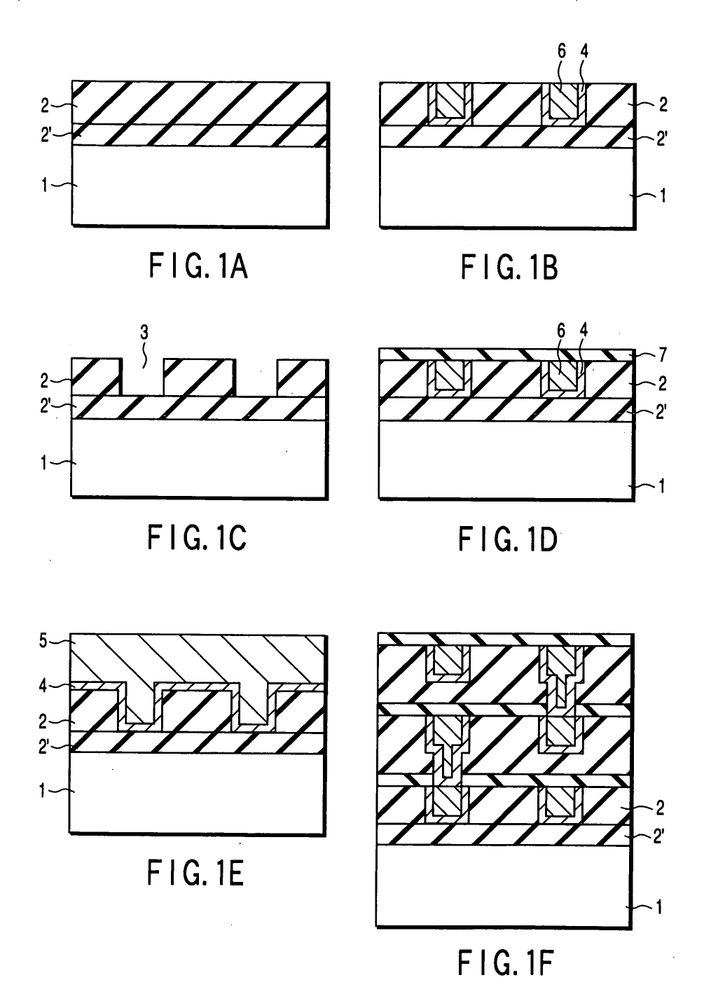

FIGS. 1A through 1F are cross-sectional views, each illustrating the method of forming damascene wiring portions of a semiconductor device provided with Cu multi-layer wiring according to one example of the present invention.

First of all, as shown in FIG. 1A, an insulating layer 2 is formed by means of chemical vapor deposition (CVD), sputtering or spin-coating on the surface of a semiconductor substrate 1 provided in advance with a transistor (not shown), with an insulating film 2′ formed on the transistor and with contact plugs (not shown).

Next, through the combined use of photolithography and etching, a predetermined wiring groove pattern 3 was formed in the insulating layer 2 as shown in FIG. 1B. Then, as required, the resultant structure was subjected to heat treatment at a temperature of 200 to 500° C. in an inert atmosphere, in an atmosphere containing hydrogen, or in a vacuum, to a plasma treatment in an atmosphere containing ammonia, or to a treatment using an ammonia solution. As a result of these treatments, it was possible to confine the surface concentration of sulfur or fluorine to the range of 10⁻³ atomic % to 1 atomic % even if sulfur or fluorine was allowed to remain on the surface of the insulating layer 2 including the wiring grooves 3.

Then, as shown in FIG. 1C, a barrier metal and a seed layer were formed by means of sputtering or the CVD method, which was followed by the filling of Cu into the wiring grooves 3 by means of plating, thereby forming a conductive diffusion-prevention layer 4 and a Cu layer 5. Subsequently, as required, heat treatment was performed at a temperature of 200 to 500° C. in an inert atmosphere, in an atmosphere containing hydrogen, or in a vacuum. As a result of these treatments, it was possible to confine the surface concentration of sulfur or fluorine to the range of 10⁻³ atomic % to 1 atomic % even if sulfur or fluorine was allowed to remain in the Cu layer 5.

If it is desired to incorporate sulfur in the Cu with excellent controllability, a sputter target containing the sulfur element may be employed to form a seed layer, or a CVD method using a raw material gas containing sulfur may be employed to form a seed layer prior to the formation of Cu layer 5 by means of plating, thereby making it possible to obtain a Cu film having a desired concentration of sulfur after a subsequent heating step.

The same procedures can be applied to the case where fluorine is to be employed. Namely, a CVD method using a raw material gas containing fluorine may be employed to form a seed layer, thereby making it possible to obtain a Cu film having a desired concentration of fluorine.

Thereafter, as shown in FIG. 1D, by means of chemical mechanical polishing, the portions of the Cu layer 5 and of the conductive diffusion-prevention layer 4, which are deposited on regions other than the inner surface of the wiring grooves 3 are removed thereby to form a Cu layer 6.

Then, as required, the resultant structure was subjected to heat treatment at a temperature of 200 to 500° C. in an inert atmosphere, in an atmosphere containing hydrogen, or in a vacuum, to a plasma treatment in an atmosphere containing ammonia, or to a treatment using an ammonia solution. As a result of these treatments, it was possible to confine the surface concentration of sulfur or fluorine to the range of 10⁻³ atomic % to 1 atomic % even if sulfur or fluorine was allowed to remain on the surfaces of the Cu wiring pattern 6 and the insulating layer 2.

Then, as shown in FIG. 1E, by means of the CVD method, etc., an insulating layer 7 which was relatively low in the diffusion coefficient of Cu and capable of suppressing the penetration of the sulfur or fluorine component, such as SiN and SiC was deposited, thereby making it possible to form a Cu wiring layer as a first layer.

In the above process, one example of forming single damascene wiring of Cu was exemplified. However, the present invention should not be construed as being limited to such an example, but can be applied to the case where dual damascene is employed. Further, it is possible to form Cu multi-layer wiring as shown in FIG. 1F by repeating the aforementioned process.

### EXAMPLE 2

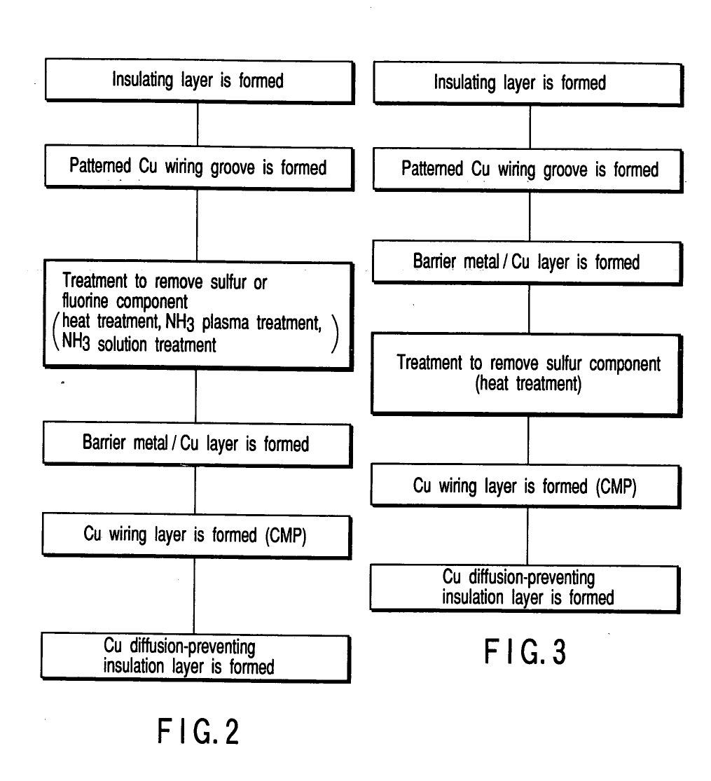

FIGS. 2, 3, 4 and 5 show respectively a flowchart illustrating, stepwise, the manufacturing process of a semiconductor device having a damascene wiring structure as Cu wiring.

FIG. 2 shows a process wherein a sulfur or fluorine component was allowed to remain on the surface of the insulating layer 2 including the inner surface of the wiring groove pattern 3 after a predetermined wiring groove pattern 3 was formed in the insulating layer 2 as shown in FIG. 1B. In this case, the fluorine component was allowed to remain on the surface of the insulating layer 2 when the wiring groove pattern 3 was etched by making use of a CF-based etching gas, whereas the sulfur component was allowed to remain on the surface of the insulating layer 2 when the surface of the insulating layer 2 was treated by making use of a treatment solution containing sulfur after the aforementioned etching process.

After a wiring groove pattern 3 was formed in this insulating layer 2, the resultant structure was subjected to heat treatment at a temperature of 200 to 500° C. in an inert atmosphere, in an atmosphere containing hydrogen or in a vacuum, to a plasma treatment in an atmosphere containing ammonia, or to a treatment using an ammonia solution, thereby making it possible to confine the surface concentration of the sulfur or fluorine component to the range of 10⁻³ atomic % to 1 atomic %.

FIG. 3 shows a process wherein a sulfur component was allowed to remain in the Cu layer 5 that had been formed by means of plating as shown in FIG. 1C. Namely, since the deposition of a Cu layer by means of plating is generally performed using a copper sulfate solution as a plating solution, sulfur was allowed to remain in the Cu layer 5.

After the deposition of the Cu layer 5 was finished as described above, the resultant structure was subjected to heat treatment at a temperature of 200 to 500° C. in an inert atmosphere, in an atmosphere containing hydrogen or in a vacuum, thereby making it possible to confine the surface concentration of the sulfur component to the range of 10⁻³ atomic % to 1 atomic %.

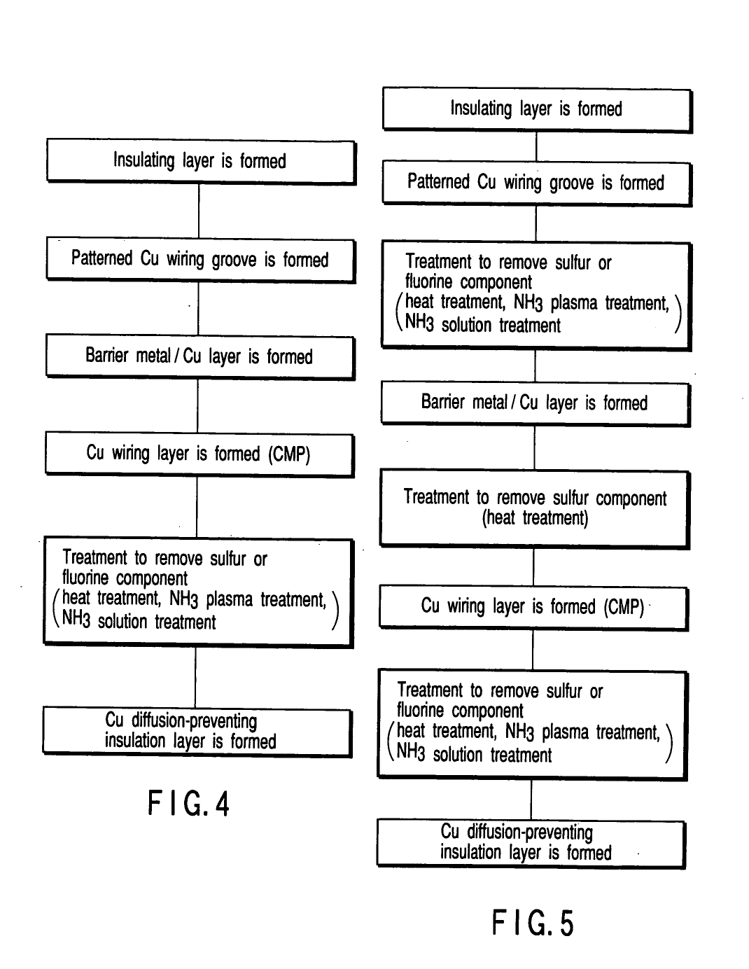

FIG. 4 shows a process wherein a sulfur or fluorine component was allowed to remain on the surfaces of the Cu wiring pattern 6 and the insulating layer 2 as a result of procedures wherein the conductive diffusion-prevention layer 4 and the Cu layer 5 were selectively removed by means of the CMP method as shown in FIG. 1D. Namely, since the CMP method was performed by making use of a polishing solution containing ammonium peroxodisulfate, sulfur was allowed to remain on the polished surface. Further, since the insulating film 2 was exposed as a result of the polishing, a fluorine component in a CF-based etching gas that had penetrated the insulating film 2 would give rise to a problem.

After the formation of the Cu wiring 6 by means of CMP method, the resultant structure was subjected to a heat treatment at a temperature of 200 to 500° C. in an inert atmosphere, in an atmosphere containing hydrogen or in a vacuum, to a plasma treatment in an atmosphere containing ammonia, or to a treatment using an ammonia solution, thereby making it possible to confine the surface concentration of the sulfur or fluorine component to the range of 10⁻³ atomic % to 1 atomic %.

FIG. 5 shows a process wherein a sulfur or fluorine component was allowed to remain on the surface of the insulating layer 2 including the inner surface of the wiring groove pattern 3, and at the same time, the sulfur component was allowed to remain in the deposited Cu layer 5, and the sulfur or fluorine component was allowed to remain on the surfaces of the Cu wiring pattern and the insulating layer 2. The causes which brought about the generation of residual sulfur and fluorine components after these steps were the same as explained above.

By performing the aforementioned treatments in the same manner as mentioned above, it was possible to confine the surface concentration of the sulfur and fluorine components to the range of 10⁻³ atomic % to 1 atomic %.

As explained above, according to the present invention, since the concentration of the sulfur or fluorine component, each giving rise to the formation of compounds as a result of reaction thereof with Cu at a temperature of 400° C., can be confined to not more than 1 atomic % in a wiring structure having a Cu-based wiring layer formed on a semiconductor substrate, it becomes possible to prevent the generation of an abnormal reaction portion or abnormal growth portion in a Cu pattern and at the same time, to effectively prevent film peeling originating from these abnormalities.

Further, since the concentration of the sulfur or fluorine component, both being impurities, is controlled to 10⁻³ atomic % or more, the coefficient of thermal expansion of Cu can be lowered, thereby making it possible to prevent film peeling, which otherwise might have occurred due to this coefficient of thermal expansion.

As explained above, since the concentration of the sulfur or fluorine component is controlled so as to fall within the range of 10⁻³ atomic % to 1 atomic %, it becomes possible to easily form a Cu-based wiring structure immune to the film peeling.

When a low permittivity insulating film exhibiting a relative permittivity of not more than 3.0 such as a coating type organic insulating film or a porous insulating film is employed as an insulating layer, not only a chemical solution containing a sulfur component, but also gaseous molecules in the etching gas are prone to be absorbed by a modified region that has been exposed to the etching gas, etc., so that as the steps of lamination proceed, sulfur or fluorine is allowed to react with Cu to produce copper sulfide compounds or copper fluoride compounds, thereby increasing the possibility of generating a defective pattern or film peeling. Therefore, the present invention is especially effective in the fabrication of a Cu-based multi-layer wiring structure wherein a low permittivity insulating film is employed as an insulating film.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a Cu-based wiring layer containing a Cu-based metal as a main component and formed on a surface of a semiconductor substrate; and
an insulating layer formed to surround said Cu-based wiring layer;
wherein said Cu-based metal contains sulfur at a ratio ranging from 10⁻³ atomic % to 1 atomic %.

2. The semiconductor device according to claim 1, wherein the content of sulfur in said Cu-based metal is in a range of 10⁻² atomic % to 1 atomic %.

3. The semiconductor device according to claim 1, wherein said Cu-based wiring layer is formed inside a wiring groove which is formed in said insulating layer.

4. The semiconductor device according to claim 3, wherein a conductive diffusion-prevention layer is formed on an inner surface of said wiring groove.

5. The semiconductor device according to claim 4, wherein said conductive diffusion-prevention layer contains one kind of material selected from the group consisting of Ta, TaN, Ti, TiN, WN, and TiSiN.

6. The semiconductor device according to claim 3, wherein an insulating diffusion-prevention layer is formed on an upper surface of said Cu-based wiring layer which is formed in said wiring groove.

7. The semiconductor device according to claim 6, wherein said insulating diffusion-prevention layer contains one kind of material selected from the group consisting of SiN, SiC, SiCO and SiCN.

8. The semiconductor device according to claim 3, wherein the content of sulfur in said insulating layer where said wiring groove is provided is in a range of 0 to 1 atomic %.

9. The semiconductor device according to claim 1, wherein a relative permittivity of said insulating layer is 3.0 or less.

10. The semiconductor device according to claim 1, wherein said Cu-based metal is Cu or a Cu alloy selected from the group consisting of Cu—Ag, Cu—Pt, Cu—Al, Cu—Co and Cu—C.

11. A semiconductor device comprising:
a Cu-based wiring layer containing a Cu-based metal as a main component and formed on a surface of a semiconductor substrate; and
an insulating layer formed to surround said Cu-based wiring layer;
wherein said Cu-based metal contains fluorine at a ratio ranging from 10⁻³ atomic % to 1 atomic %.

12. The semiconductor device according to claim 11, wherein the content of fluorine in said Cu-based metal is in a range of 10⁻² atomic % to 1 atomic %.

13. The semiconductor device according to claim 11, wherein said Cu-based wiring layer is formed inside a wiring groove which is formed in said insulating layer.

14. The semiconductor device according to claim 13, wherein a conductive diffusion-prevention layer is formed on an inner surface of said wiring groove.

15. The semiconductor device according to claim 14, wherein said conductive diffusion-prevention layer contains one kind of material selected from the group consisting of Ta, TaN, Ti, TiN, WN, and TiSiN.

16. The semiconductor device according to claim 13, wherein an insulating diffusion-prevention layer is formed on an upper surface of said Cu-based wiring layer which is formed in said wiring groove.

17. The semiconductor device according to claim 16, wherein said insulating diffusion-prevention layer contains one kind of material selected from the group consisting of SiN, SiC, SiCO and SiCN.

18. The-semiconductor device according to claim 13, wherein the content of fluorine in said insulating layer where said wiring groove is provided is in a range of 0 to 1 atomic %.

19. The semiconductor device according to claim 11, wherein a relative permittivity of said insulating layer is 3.0 or less.

20. The semiconductor device according to claim 11, wherein said Cu-based metal is Cu or a Cu alloy selected from the group consisting of Cu—Ag, Cu—Pt, Cu—Al, Cu—Co and Cu—C.

21. A method of manufacturing a semiconductor device, which comprises:
forming an insulating layer on a surface of a semiconductor substrate;
forming a wiring groove pattern in said insulating layer;
subjecting a resultant structure to a heat treatment in an inert atmosphere, in an atmosphere containing hydrogen or in a vacuum, to a plasma treatment in an atmosphere containing ammonia, or to a treatment using an ammonia solution;
forming a conductive diffusion-prevention layer on an inner surface of said wiring groove that has been subjected to any of the aforementioned treatments and on a surface of said insulating layer that has been subjected to any of aforementioned treatments;
forming a Cu-based metal layer on a surface of said conductive diffusion-prevention layer thereby to bury said wiring groove with a Cu-based metal;
selectively removing portions of the Cu-based metal layer and of said conductive diffusion-prevention layer, which are deposited on regions other than the inner surface of said wiring groove thereby to form a Cu-based wiring layer inside said wiring groove; and
forming an insulating film which is capable of suppressing the diffusion of Cu-based metal on a surface of said Cu-based wiring layer and on a surface of said insulating layer;
wherein said Cu-based metal contains sulfur or fluorine at a ratio ranging from 10⁻³ atomic % to 1 atomic %.

22. The method according to claim 21, wherein the content of sulfur or fluorine in said Cu-based metal is in a range of 10⁻² atomic % to 1 atomic %.

23. The method according to claim 21, wherein the content of sulfur or fluorine in said insulating layer which has been subjected to any of the aforementioned treatments is in a range of 0 to 1 atomic %.

24. The method according to claim 21, wherein the temperature of said heat treatment is in a range of 200 to 500° C.

25. A method of manufacturing a semiconductor device, which comprises:
forming an insulating layer on a surface of a semiconductor substrate;
forming a wiring groove pattern in said insulating layer;
forming a conductive diffusion-prevention layer on an inner surface of said wiring groove and on a surface of said insulating layer;
forming a Cu-based metal layer on a surface of said conductive diffusion-prevention layer thereby to bury said wiring groove with a Cu-based metal;
subjecting a resultant structure to a heat treatment in an inert atmosphere, in an atmosphere containing hydrogen or in a vacuum;
selectively removing portions of Cu-based metal layer and of said conductive diffusion-prevention layer, which are deposited on regions other than the inner surface of said wiring groove thereby to form a Cu-based wiring layer inside said wiring groove; and
forming an insulating film which is capable of suppressing the diffusion of Cu-based metal on a surface of said Cu-based wiring layer and on a surface of said insulating layer;
wherein said Cu-based metal contains sulfur at a ratio ranging from 10⁻³ atomic % to 1 atomic %.

26. The method according to claim 25, wherein the content of sulfur in said Cu-based metal is in a range of 10⁻² atomic % to 1 atomic %.

27. The method according to claim 25, wherein the content of sulfur in said insulating layer which has been subjected to any of the aforementioned treatments is in a range of 0 to 1 atomic %.

28. The method according to claim 25, wherein the temperature of said heat treatment is in a range of 200 to 500° C.

29. A method of manufacturing a semiconductor device, which comprises:
forming an insulating layer on a surface of a semiconductor substrate;
forming a wiring groove pattern in said insulating layer;
forming a conductive diffusion-prevention layer on an inner surface of said wiring groove and on a surface of said insulating layer;
forming a Cu-based metal layer on a surface of said conductive diffusion-prevention layer thereby to bury said wiring groove with a Cu-based metal;
selectively removing portions of the Cu-based metal layer and of said conductive diffusion-prevention layer, which are deposited on regions other than the inner surface of said wiring groove thereby to form a Cu-based wiring layer inside said wiring groove;
subjecting a resultant structure having said Cu-based wiring layer formed therein to a heat treatment in an inert atmosphere, in an atmosphere containing hydrogen or in a vacuum, to a plasma treatment in an atmosphere containing ammonia, or to a treatment using an ammonia solution; and
forming an insulating diffusion-prevention layer which is capable of suppressing the diffusion of Cu-based metal on a surface of said Cu-based wiring layer and on a surface of said insulating layer;
wherein said Cu-based metal contains sulfur or fluorine at a ratio ranging from 10⁻³ atomic % to 1 atomic %.

30. The method according to claim 29, wherein the content of sulfur or fluorine in said Cu-based metal is in a range of 10⁻² atomic % to 1 atomic %.

31. The method according to claim 29, wherein the content of sulfur or fluorine in said insulating layer which has been subjected to any of the aforementioned treatments is in a range of 0 to 1 atomic %.

32. The method according to claim 29, wherein the temperature of said heat treatment is in a range of 200 to 500° C.

33. A method of manufacturing a semiconductor device, which comprises:
forming an insulating layer on a surface of a semiconductor substrate;
forming a wiring groove pattern in said insulating layer;
subjecting a resultant structure to a heat treatment in an inert atmosphere, in an atmosphere containing hydrogen or in a vacuum, to a plasma treatment in an atmosphere containing ammonia, or to a treatment using an ammonia solution;
forming a conductive diffusion-prevention layer on an inner surface of said wiring groove and on a surface of said insulating layer;
forming a Cu-based metal layer on a surface of said conductive diffusion-prevention layer thereby to bury said wiring groove with a Cu-based metal;
subjecting said Cu-based metal layer to a heat treatment in an inert atmosphere, in an atmosphere containing hydrogen or in a vacuum;
selectively removing portions of the Cu-based metal layer and of said conductive diffusion-prevention layer, which are deposited on regions other than the inner surface of said wiring groove thereby to form a Cu-based wiring layer inside said wiring groove;
subjecting a resultant structure having said Cu-based wiring layer formed therein to a heat treatment in an inert atmosphere, in an atmosphere containing hydrogen or in a vacuum, to a plasma treatment in an atmosphere containing ammonia, or to a treatment using an ammonia solution; and
forming an insulating diffusion-prevention layer which is capable of suppressing the diffusion of Cu-based metal on a surface of said Cu-based wiring layer and on a surface of said insulating layer;
wherein said Cu-based metal contains sulfur or fluorine at a ratio ranging from 10⁻³ atomic % to 1 atomic %.

34. The method according to claim 33, wherein the content of sulfur or fluorine in said Cu-based metal is in a range of 10⁻² atomic % to 1 atomic %.

35. The method according to claim 33, wherein the content of sulfur or fluorine in said insulating layer which has been subjected to any of the aforementioned treatments is in a range of 0 to 1 atomic %.

36. The method according to claim 33, wherein the temperature of said heat treatment is in a range of 200 to 500° C.
